(19) United States
(12) Patent Application Publication
(10) Pub. No.: US 2026/0221893 A1
(43) Pub. Date: Jul. 30, 2026

(54) CONVERTER ASSEMBLY

(71) Applicant: ABB Schweiz AG, Baden (CH)

(72) Inventors: Jari Tapio Savolainen, Helsinki (FI); Vesa Palojoki, Helsinki (FI); Matti Mielonen, Helsinki (FI); Matti Kauranen, Helsinki (FI)

(21) Appl. No.: 19/453,400

(22) Filed: Jan. 20, 2026

(30) Foreign Application Priority Data
Jan. 27, 2025 (EP) 25154132.2

(51) Int. Cl. H02M 7/00; H02B 1/01; H02B 1/30; H02B 1/42; H02M 1/08; H02M 3/00; H05K 7/14

(52) U.S. Cl. CPC H02M 7/003; H02B 1/012; H02B 1/301; H02B 1/305; H02B 1/42; H02M 1/08; H02M 3/003; H05K 7/14322; H05K 7/14339

(57) ABSTRACT

A converter assembly is provided that includes a frame and a plurality of electrical components mounted on the frame, the electrical components including an electrical converter. A converter connector system is mounted on the frame and includes at least one input connector and at least one output connector. The converter assembly further includes a cabling wall having a plurality of cabling apertures, each cabling aperture extending through the cabling wall in a longitudinal direction and being configured to receive a cable. A cabling module comprising the cabling wall is adapted to be removably fastened to the frame and is configured to be positioned on the frame in an operational position.

### CROSS-REFERENCE TO RELATED APPLICATIONS

This application claims priority to European Patent Application No. 25154132.2 filed on Jan. 27, 2025, and titled “CONVERTER ASSEMBLY”, the entire contents of which are hereby incorporated by reference.

### TECHNICAL FIELD

The present disclosure relates to a converter assembly.

### BACKGROUND

A known converter assembly comprises a frame, a plurality of electrical components mounted on the frame, and a cabling wall having a plurality of cabling apertures. The plurality of electrical components includes an electrical converter, and the cabling apertures are adapted to receive a plurality of cables for electrically connecting the electrical converter to a power supply and to a load.

One of the shortcomings associated with the known converter assembly is that maintenance or replacement of some of the plurality of electrical components is laborious since the cables block access to the electrical components, and the cabling wall prevents bending the cables sufficiently to provide the access to the electrical components without damaging the cables.

### BRIEF DESCRIPTION

An object of the present disclosure is to provide a converter assembly so as to solve the above problem. The objects of the disclosure are achieved by a converter assembly described in the following.

The present disclosure is based on the idea of providing a converter assembly with a cabling module adapted to be removably fastened to a frame of the converter assembly. The removable cabling module comprises a cabling wall having a plurality of cabling apertures through which cables connected to a converter connector system extend in an operational state of the converter assembly.

An advantage of the converter assembly of the present disclosure is that the removable cabling module facilitates maintenance of the converter assembly by enabling the cabling wall to be moved relative to the frame of the converter assembly. The removable cabling module enables moving cables further from electrical components requiring maintenance while maintaining bending radii of the cables within an allowable range. Consequently, cables blocking access to electrical components requiring maintenance can be moved out of the way without a need to withdraw the cables from the cabling apertures or to bend the cables excessively. Further, the removable cabling module enables replacing the frame of the converter assembly, together with electrical components mounted on the frame, without a need to withdraw cables from the plurality of cabling apertures or to bend the cables excessively.

### BRIEF DESCRIPTION OF DRAWINGS

In the following, the present disclosure will be described in greater detail by means of some embodiments with reference to the attached drawings, in which:

FIG. 1 shows a converter assembly according to an embodiment of the present disclosure;

FIG. 2 shows the converter assembly of FIG. 1 without a front cover and side covers;

FIG. 3 is a side view of the converter assembly shown in FIG. 2;

FIG. 4 shows the converter assembly of FIG. 2 in a situation in which a cabling module has been unfastened from a frame of the converter assembly; and

FIG. 5 is a side view of the converter assembly shown in FIG. 4.

### DETAILED DESCRIPTION

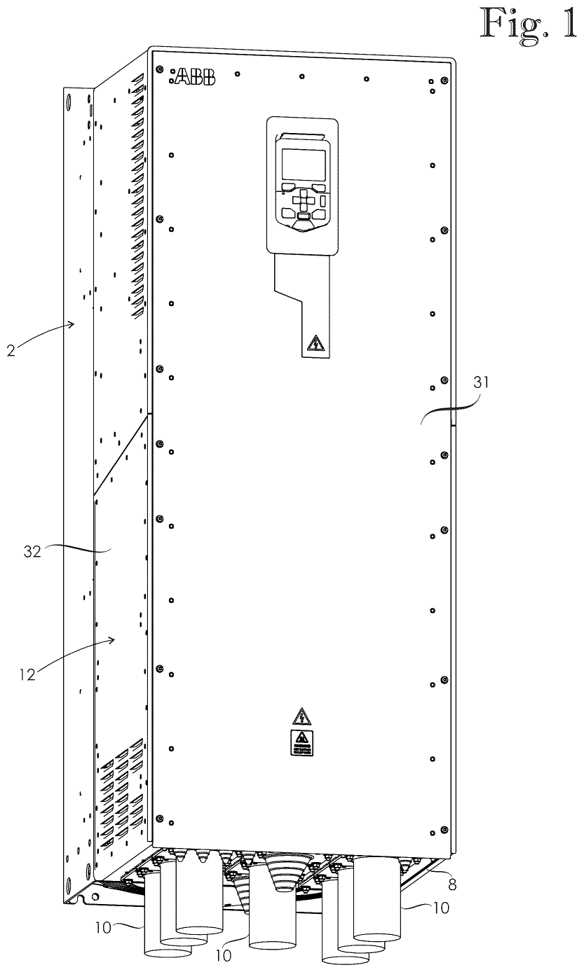

FIG. 1 shows a converter assembly comprising a frame 2, a front cover 31, side covers 32, a plurality of electrical components mounted on the frame 2, a cabling module 12, a converter connector system, a cabling module connector system and seven cables 10 electrically connected to the plurality of electrical components.

The cabling module 12 is removably fastened to the frame 2 by means of a plurality of bolt joints. In an alternative embodiment, the cabling module is adapted to be removably fastened to the frame by means of at least one bolt joint.

In FIG. 1, the cabling module 12 is in an operational position relative to the frame 2.

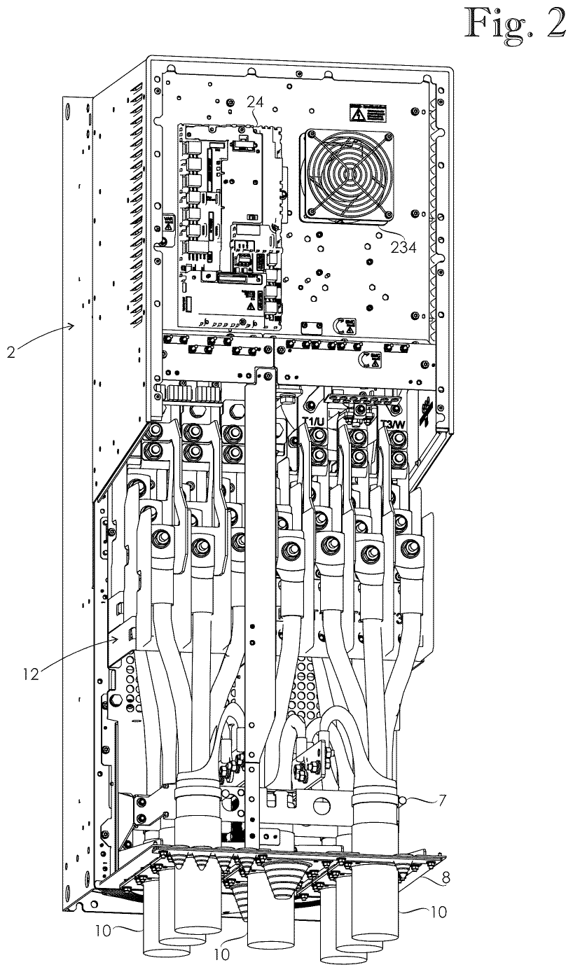

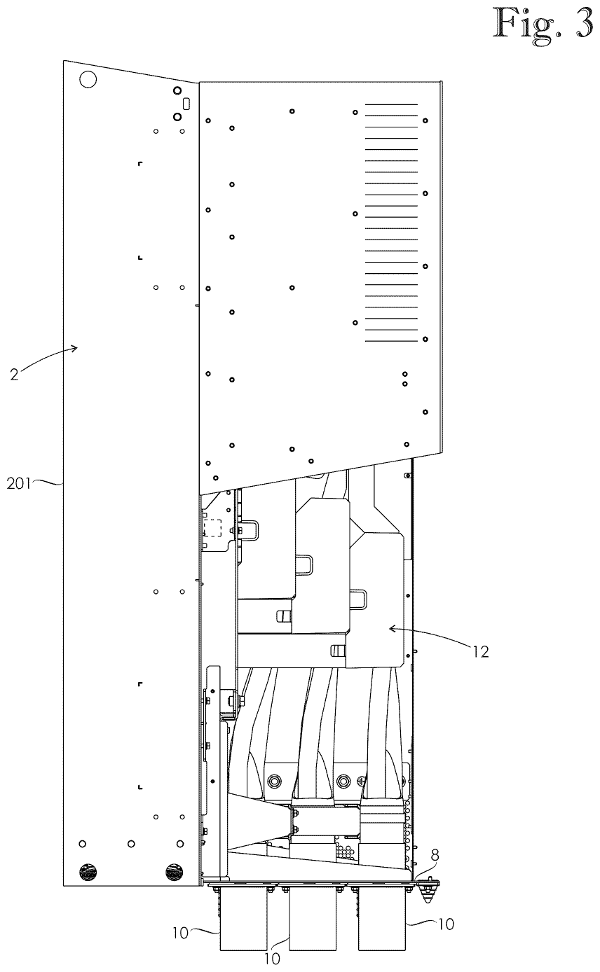

FIG. 2 shows the converter assembly of FIG. 1 without the front cover 31 and side covers 32. FIG. 3 is a side view of the converter assembly shown in FIG. 2.

The frame 2 has a back wall 201 defining a back wall plane. The back wall plane is parallel to a plane defined by a longitudinal direction and a width direction perpendicular to the longitudinal direction. In FIG. 3, the longitudinal direction is the vertical direction, and the width direction is perpendicular to the image plane.

The converter assembly is adapted to be mounted on a wall of an assembly space such that the back wall 201 is adjacent to the wall of the assembly space, and the back wall plane is parallel to a plane defined by the wall of the assembly space. In an embodiment, the assembly space is a room of a building. In another embodiment, the assembly space is an engine room of a ship. In yet another embodiment, the assembly space is an electrical cabinet.

The frame 2 is provided with at least one support member for supporting the frame 2 to an assembly space. In an embodiment, the at least one support member comprises at least one leg by means of which the frame is adapted to stand on a floor. In another embodiment, the at least one support member comprises at least one bolt hole each one of which is adapted to receive a bolt for connecting the frame to a wall or a floor.

A width of the cabling module 12 is substantially equal to a width of the frame 2. In the longitudinal direction and in a depth direction perpendicular to both the longitudinal direction and the width direction, a dimension of the cabling module 12 is roughly half the dimension of the frame 2. In an alternative embodiment, a ratio between dimensions of the cabling module and the frame in the width direction is in a range of 50-105%, a ratio between dimensions of the cabling module and the frame in the longitudinal direction in a range of 20-105%, and a ratio between dimensions of the cabling module and the frame in the depth direction in a range of 10-90%.

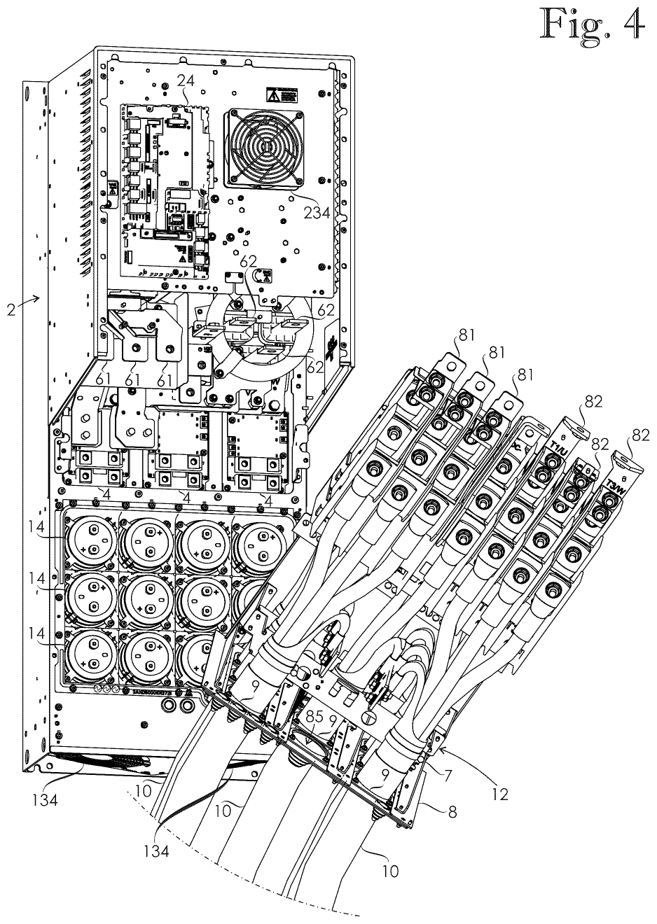

FIG. 4 shows the converter assembly of FIG. 2 in a situation in which the cabling module 12 has been unfastened from the frame 2 of the converter assembly and moved further from the frame 2.

The plurality of electrical components mounted on the frame 2 includes an electrical converter, twelve capacitors 14, a control unit 24, two main fans 134 and an auxiliary fan 234. The electrical converter has three semiconductor switch units 4. The control unit 24 is adapted to control the semiconductor switch units 4. The two main fans 134 are adapted for cooling the electrical converter and the capacitors 14. The auxiliary fan 234 is adapted for cooling the control unit 24. In an alternative embodiment, the converter assembly comprises at least one main fan adapted for cooling the electrical converter.

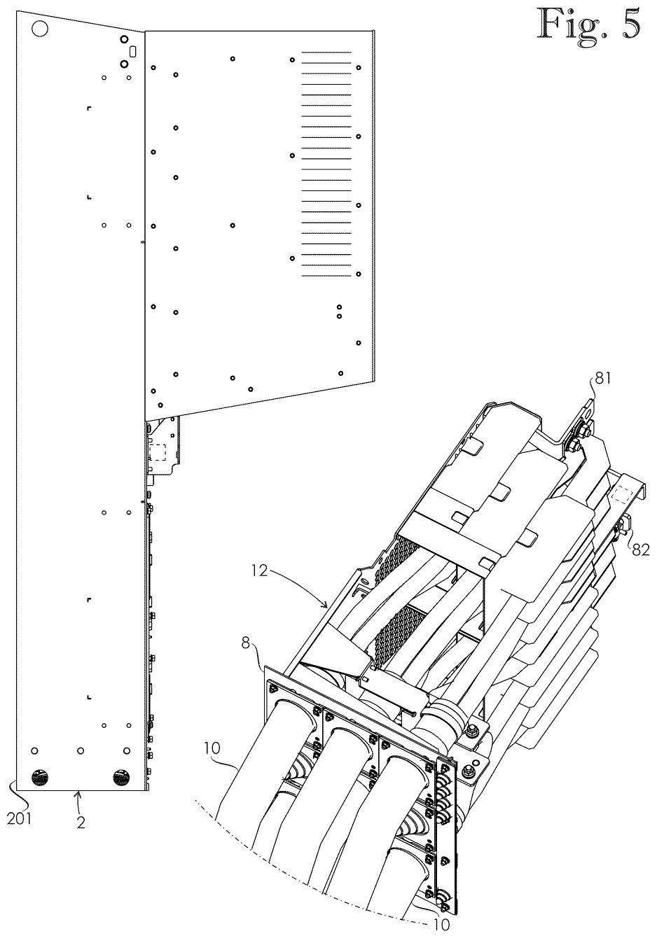

In the embodiment shown in FIGS. 1 to 5, the electrical converter is a frequency converter. Input and output power of the frequency converter is adapted to pass through the semiconductor switch units 4. The capacitors 14 are electrically connected to a DC intermediate circuit of the frequency converter.

In an alternative embodiment, the electrical converter is another type of converter adapted to convert electric energy from one form to another. Examples of electrical converter comprise an inverter, a rectifier and a DC-to-DC converter.

In an embodiment, the nominal input voltage of the electrical converter is greater than or equal to 100 V, and the nominal power of the electrical converter is greater than or equal to 20 kVA.

The converter connector system is mounted on the frame 2. The converter connector system includes three input connectors 61 and three output connectors 62.

Each input connector 61 is electrically connected to an input of the electrical converter and is adapted to be electrically connected to a power supply. Each input connector 61 comprises an internal thread for connecting the input connector 61 to a counterpart connector by means of a bolt joint.

Each output connector 62 is electrically connected to an output of the electrical converter and is adapted to be electrically connected to a load. Each output connector 62 comprises a bolt hole for connecting the output connector 62 to a counterpart connector by means of a bolt joint.

The cabling module 12 has a cabling wall 8 comprising nine cabling apertures 85. The cabling apertures 85 are circular apertures. In an embodiment, a surface area of each of the cabling apertures is greater than or equal to 100 mm². In an alternative embodiment, a surface area of each of the cabling apertures is greater than or equal to 200 mm².

In the operational position of the cabling module 12, each of the cabling apertures 85 extends through the cabling wall 8 in the longitudinal direction and is adapted for receiving a cable. In FIG. 1, seven of the cabling apertures 85 accommodates a cable 10 each while two of the cabling apertures are vacant.

The cabling wall 8 defines a cabling wall plane. In the operational position of the cabling module 12, a normal of the cabling wall plane is parallel to the longitudinal direction. In an alternative embodiment, in the operational position of the cabling module, an angle between a normal of the cabling wall plane and the longitudinal direction is less than or equal to 20°.

There is a lead-through seal 9 between each of the plurality of cables 10 and an edge of a corresponding cabling aperture 85. Further, the vacant cabling apertures are blocked by seals. Each of the cables 10 is fastened to the cabling module 12 with a corresponding cable clamp 7.

Each of the cables 10 has three conductors such that a total cross-sectional area of the conductors is 75 mm². In an alternative embodiment, each of the cables has at least one conductor such that a total cross-sectional area of the at least one conductor is greater than or equal to 25 mm².

In an embodiment, the distance in the longitudinal direction between the converter connector system and the cabling wall is greater than or equal to 150 mm. Herein, the distance between the converter connector system and the cabling wall is the shortest distance in the longitudinal direction between the cabling wall and any one of the input connectors and output connectors. Typically, a minimum distance between the converter connector system and the cabling wall is determined by bending space requirements or bending radius requirements given in relevant standards.

The plurality of electrical components mounted on the frame 2 includes a first set of components such that on the back wall plane, a projection of the first set of components at least partially overlaps with a projection of the cabling module 12, and the first set of components is located between the back wall 201 and the cabling module 12 in the depth direction perpendicular to the back wall plane. In other words, in the operational position of the cabling module 12, components of the first set of components are at least partially located behind the cabling module 12. Further, in the operational state of the converter assembly, components of the first set of components are at least partially located behind the cables 10.

The first set of components comprises the semiconductor switch units 4 and the capacitors 14. In an alternative embodiment, the first set of components comprises at least one choke coil electrically connected to output connectors of the frequency converter.

The cabling module connector system is mounted on the cabling module 12 and is stationary relative to the cabling wall 8. The cabling module connector system is adapted to be electrically and conductively connected to the converter connector system by means of a plurality of bolt joints. The cabling module connector system is adapted to be electrically and conductively connected to the cables 10 extending through the plurality of cabling apertures 85.

The cabling module connector system comprises three input connectors 81 adapted to be electrically connected to the input connectors 61 of the converter connector system, and three output connectors 82 adapted to be electrically connected to the output connectors 62 of the converter connector system. In an alternative embodiment, the cabling module connector system is adapted to be electrically and conductively connected to the converter connector system by means of a removable connection provided without bolts or nuts.

In the converter assembly shown in FIGS. 1 to 5, each of the cables 10 extending through the cabling apertures 85 of the cabling wall 8 is adapted to be electrically connected to exactly one connector of the converter connector system. In an alternative embodiment, a plurality of cables extending through the cabling apertures of the cabling wall comprises at least one set of cables having a plurality of individual cables, wherein in the operational state of the converter assembly, each cable of the at least one set of cables is electrically connected to a single electrical connector of the converter connector system.

In an embodiment, the converter connector system comprises at least one alternating current connector such that in the operational state of the converter assembly, at least one set of cables having a plurality of individual cables extending through the cabling apertures of the cabling wall is electrically connected to exactly one of the at least one alternating current connectors. For example, the converter assembly shown in FIGS. 1 to 5 could be modified such that the cables extending through the cabling wall comprise a plurality of individual cables electrically and conductively connected to a common cable connector of the cabling module connector system, wherein the common cable connector is adapted to be electrically and conductively connected to a single input connector of the converter connector system.

The disclosed concept can be implemented in various ways. The present disclosure and its embodiments are not limited to the examples described above but may vary within the scope of the claims.

The disclosed systems and methods are not limited to the specific embodiments described herein. Rather, components of the systems or activities of the methods may be utilized independently and separately from other described components or activities.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

1. A converter assembly comprising:
a frame;
a plurality of electrical components mounted on the frame, wherein the plurality of electrical components includes an electrical converter having at least one semiconductor switch unit;
a converter connector system mounted on the frame, wherein the converter connector system includes at least one input connector and at least one output connector, wherein the at least one input connector is electrically connected to an input of the electrical converter, and wherein the at least one output connector is electrically connected to an output of the electrical converter; and
a cabling wall comprising a plurality of cabling apertures, wherein each of the cabling apertures extends through the cabling wall in a longitudinal direction, and is configured to receive cable,
wherein the converter assembly comprises a cabling module configured to be removably fastened to the frame into an operational position, and wherein the cabling module comprises the cabling wall.

2. The converter assembly according to claim 1, wherein in the operational position of the cabling module, a distance in the longitudinal direction between the converter connector system and the cabling wall is greater than or equal to 150 millimetres.

3. The converter assembly according to claim 1, wherein a nominal input voltage of the electrical converter is greater than or equal to 100 Volts, and a nominal power of the electrical converter is greater than or equal to 20 Kilovolt Amperes.

4. The converter assembly according to claim 1, wherein the frame has a back wall defining a back wall plane, and wherein the back wall plane is parallel to a plane defined by the longitudinal direction and a width direction perpendicular to the longitudinal direction.

5. The converter assembly according to claim 4, wherein the converter assembly is configured to be mounted on a wall of an assembly space such that the back wall is adjacent to the wall of the assembly space, and wherein the back wall plane is parallel to a plane defined by the wall of the assembly space.

6. The converter assembly according to claim 4, wherein the plurality of electrical components includes a first set of components such that on the back wall plane, a projection of the first set of components at least partially overlaps with a projection of the cabling module, and wherein the first set of components is located between the back wall and the cabling module in a depth direction perpendicular to the back wall plane.

7. The converter assembly according to claim 1, wherein the converter assembly comprises a cabling module connector system mounted on the cabling module, wherein the cabling module connector system is configured to be electrically conductively connected to the converter connector system by means of a removable connection, and wherein the cabling module connector system is configured to be electrically conductively connected to a plurality of cables extending through the plurality of cabling apertures.

8. The converter assembly according to claim 1, wherein the cabling module is configured to be removably fastened to the frame by means of at least one bolt joint.

9. The converter assembly according to claim 1, wherein each of the at least one input connector comprises an internal thread for connecting the input connector to a counterpart connector, and/or each of the at least one output connector comprises an internal thread for connecting the output connector to a counterpart connector.

10. The converter assembly according to claim 1, wherein the converter assembly comprises a plurality of cables extending through the plurality of cabling apertures, and wherein each of the plurality of cables has at least one conductor such that a total cross-sectional area of the at least one conductor is greater than or equal to 25 millimetres squared.

11. The converter assembly according to claim 10, wherein the plurality of cables comprises at least one set of cables having a plurality of individual cables, and wherein in the operational position of the cabling module, each cable of the at least one set of cables is electrically connected to a single electrical connector of the converter connector system.

12. The converter assembly according to claim 11, wherein the converter connector system comprises at least one alternating current connector, wherein the at least one set of cables is electrically connected to a single phase, and wherein in the operational position of the cabling module, each cable of the at least one set of cables is electrically connected to a single alternating current connector of the converter connector system.

13. The converter assembly according to claim 11, wherein each cable of the at least one set of cables is electrically conductively connected to a single cable connector configured to be electrically conductively connected to the single electrical connector of the converter connector system.

14. The converter assembly according to claim 10, wherein there is a lead-through seal between each of the plurality of cables and an edge of a corresponding cabling aperture.

15. The converter assembly according to claim 10, wherein each of the plurality of cables is fastened to the cabling module with a corresponding cable clamp.

16. A converter assembly comprising:
a frame;
a plurality of electrical components mounted on the frame, wherein the plurality of electrical components includes an electrical converter having at least one semiconductor switch unit;
a converter connector system mounted on the frame, wherein the converter connector system includes at least one input connector and at least one output connector, wherein the at least one input connector is electrically connected to an input of the electrical converter, and wherein the at least one output connector is electrically connected to an output of the electrical converter; and
a cabling wall comprising a plurality of cabling apertures, wherein each of the cabling apertures extends through the cabling wall in a longitudinal direction, and is configured to receive a cable,
wherein the converter assembly comprises a cabling module configured to be removably fastened to the frame into an operational position, and wherein the cabling module comprises the cabling wall,
wherein the frame has a back wall defining a back wall plane, and wherein the back wall plane is parallel to a plane defined by the longitudinal direction and a width direction perpendicular to the longitudinal direction,
wherein the converter assembly is configured to be mounted on a wall of an assembly space such that the back wall is adjacent to the wall of the assembly space, and wherein the back wall plane is parallel to a plane defined by the wall of the assembly space, and
wherein the plurality of electrical components includes a first set of components such that on the back wall plane, a projection of the first set of components at least partially overlaps with a projection of the cabling module, and wherein the first set of components is located between the back wall and the cabling module in a depth direction perpendicular to the back wall plane.

17. The converter assembly according to claim 16, wherein in the operational position of the cabling module, a distance in the longitudinal direction between the converter connector system and the cabling wall is greater than or equal to 150 millimetres.

18. The converter assembly according to claim 16, wherein a nominal input voltage of the electrical converter is greater than or equal to 100 Volts, and wherein a nominal power of the electrical converter is greater than or equal to 20 Kilovolt amperes.

19. The converter assembly according to claim 6, wherein the converter assembly comprises a cabling module connector system mounted on the cabling module, wherein the cabling module connector system is configured to be electrically conductively connected to the converter connector system by means of a removable connection, and wherein the cabling module connector system is configured to be electrically conductively connected to a plurality of cables extending through the plurality of cabling apertures.

20. The converter assembly according to claim 12, wherein each cable of the at least one set of cables is electrically conductively connected to a single cable connector configured to be electrically conductively connected to the single electrical connector of the converter connector system.
